(19) United States
(12) Patent Application Publication
(10) Pub. No.: US 2026/0198015 A1
(43) Pub. Date: Jul. 9, 2026

(54) Magnetic Storage Unit and Preparation Method of Magnetic Storage Unit

(71) Applicant: ZHEJIANG HIKSTOR TECHNOLOGY CO., LTD., Hangzhou (CN)

(72) Inventors: Shikun HE, Hangzhou (CN); Shasha WANG, Hangzhou (CN); Kequn CHI, Hangzhou (CN)

(21) Appl. No.: 19/571,961

(22) Filed: Mar. 19, 2026

Related U.S. Application Data
(63) Continuation-in-part of application No. PCT/CN2024/119077, filed on Sep. 14, 2024.

(30) Foreign Application Priority Data
Sep. 19, 2023 (CN) 202311211420.X

(51) Int. Cl. H10B 61/00; H10N 50/01; H10N 50/10

(52) U.S. Cl. CPC H10B 61/20; H10N 50/01; H10N 50/10

(57) ABSTRACT

The present disclosure provides a magnetic storage unit. The magnetic storage unit includes: a substrate layer, including two spaced bottom electrodes; a spin-orbit torque layer, disposed on an upper surface of the substrate layer, and at least covering the two bottom electrodes; and a magnetic tunnel junction, disposed on an upper surface of the spin-orbit torque layer, and at least covering a range where the two bottom electrodes are located.

### CROSS-REFERENCE TO RELATED APPLICATION

The present disclosure is a continuation-in-part application of International Patent Application No. PCT/CN2024/119077, which is filed on Sep. 14, 2024, and claims priority to Chinese Patent Application No. 202311211420.X, filed on Sep. 19, 2023 and entitled “Magnetic Storage Unit and Preparation Method therefor”, the contents of which are hereby incorporated by reference in its entirety.

### TECHNICAL FIELD

The present disclosure relates to the field of magnetic storage technology, and in particular, to a magnetic storage unit and a preparation method of the magnetic storage unit.

### BACKGROUND

A spin-orbit torque magnetic memory, as the next-generation non-volatile magnetic random access memory, utilizes a spin-orbit torque as an information writing method, enabling spin-orbit torque devices to achieve ns-scale write speeds, and has a read-write separation mode, making the spin-orbit torque magnetic memory promising for realizing an unlimited number of write cycles.

An existing memory cell architecture for the spin-orbit torque magnetic memory, whether employing two-port or three-port technologies, is based on magnetic tunnel junction etching stopping on a spin-orbit torque material. The architectural design imposes stringent requirements on the etching, and the process directly affects electrical performance of the devices:

Firstly, precise control over an etching stop layer is needed to minimize the impact of etching-induced damage on performance of a spin-orbit torque layer. The spin-orbit torque layer is thin, only a few nanometers, and is prone to being etched through during over-etching, which results in an open circuit in an spin-orbit torque layer and device scrapping.

Secondly, magnetic tunnel junction short circuits need to be reduced (minimizing metal re-sputtering on an outer side of a barrier layer), and a device end needs to achieve a defect rate of at least 1000 ppm to enable mass production. Short circuit reduction is generally achieved by removing re-sputtered metal through an over-etching method after cutting off a metal layer. However, magnetic tunnel junction etching needs to stop on the spin-orbit torque layer. When etching stops, areas outside a magnetic tunnel junction are entirely metal, increasing the difficulty of removing metal re-sputtering.

Thirdly, since a distance between bottom electrodes is typically greater than a diameter of the magnetic tunnel junction, a large portion of the spin-orbit torque layer remains underutilized. Instead, it causes the memory to generate high heat during use due to large resistance, resulting in high power consumption.

### SUMMARY

The present disclosure provides a magnetic storage unit and a preparation method therefor to provide a large over-etching window, thereby significantly reducing short circuits caused by re-sputtering, while reducing a probability of a spin-orbit torque layer being over-etched and etched through, to improve a device yield.

In a first aspect, the present disclosure provides a magnetic storage unit, including:
a substrate layer, which includes two spaced bottom electrodes;
a spin-orbit torque layer, disposed on an upper surface of the substrate layer, and at least covering the two bottom electrodes; and
a magnetic tunnel junction, disposed on an upper surface of the spin-orbit torque layer, and at least covering a range where the two bottom electrodes are located.

In some embodiments, an edge of the magnetic tunnel junction is aligned with an edge of the spin-orbit torque layer.

In some embodiments, the magnetic tunnel junction includes a ferromagnetic layer, a barrier layer, and a pinned layer, and the ferromagnetic layer is located above an spin-orbit torque layer and is in direct contact with the spin-orbit torque layer.

In some embodiments, the magnetic storage unit further includes:
a first hard mask layer, which is disposed on an upper surface of the magnetic tunnel junction, with an edge of the first hard mask layer aligned with the edge of the magnetic tunnel junction.

In some embodiments, the magnetic storage unit further includes:
a magnetic layer, which is disposed on an upper surface of the first hard mask layer, with an edge of the magnetic layer aligned with the edge of the first hard mask layer.

In some embodiments, a magnetization direction of the magnetic layer is located in a plane of the magnetic layer or in a normal direction of the magnetic layer.

In some embodiments, the two bottom electrodes are disposed in a major axis direction of the spin-orbit torque, or a disposition direction of the two bottom electrodes forms an included angle with the major axis direction.

In some embodiments, a magnetization direction of a free layer of the magnetic tunnel junction is disposed in a major axis direction of the free layer, or the magnetization direction of the free layer of the magnetic tunnel junction is disposed in a normal direction of the free layer.

In some embodiments, the magnetic tunnel junction is rectangular or elliptical in shape.

In some embodiments, an aspect ratio of the magnetic tunnel junction is less than 6.

In some embodiments, the two bottom electrodes are circular or elliptical in shape.

In some embodiments, when the two bottom electrodes are elliptical, a major axis direction of each bottom electrode is perpendicular to a major axis direction of the magnetic tunnel junction.

In some embodiments, the magnetic storage unit further includes:
a second hard mask layer, which is disposed on a upper surface of the magnetic layer, with an edge of the second hard mask layer aligned with an edge of the magnetic layer.

In a second aspect, the present disclosure also provides a preparation method for a magnetic storage unit. The method includes:
providing a substrate layer with two bottom electrodes;
sequentially forming a spin-orbit torque layer and a magnetic tunnel junction on the substrate layer; and
performing a single etching process on the magnetic tunnel junction and the spin-orbit torque layer using the same mask, and controlling an etching endpoint to be no higher than a lower surface of the spin-orbit torque layer.

In some embodiments, the performing a single etching process on the magnetic tunnel junction and the spin-orbit torque layer using the same mask includes:
forming a first hard mask layer on an upper surface of the magnetic tunnel junction; and
performing a single etching process on the first hard mask layer, the magnetic tunnel junction, and the spin-orbit torque layer using the same mask, and controlling an etching endpoint to be no higher than the lower surface of the spin-orbit torque layer.

In some embodiments, the performing a single etching process on the first hard mask layer, the magnetic tunnel junction, and the spin-orbit torque layer using the same mask includes:
forming a magnetic layer on an upper surface of the first hard mask layer; and
performing a single etching process on the magnetic layer, the first hard mask layer, the magnetic tunnel junction, and the spin-orbit torque layer using the same mask, and controlling an etching endpoint to be no higher than the lower surface of the spin-orbit torque layer.

In some embodiments, when the two bottom electrodes are elliptical, a major axis direction of each bottom electrode is perpendicular to a major axis direction of the magnetic tunnel junction.

In some embodiments, a distance between the etching endpoint and the lower surface of the spin-orbit torque layer is greater than 5 nm.

In some embodiments, providing a substrate layer with two bottom electrodes includes:
depositing a dielectric layer on a substrate having the two bottom electrodes formed thereon;
patterning and etching the dielectric layer to form bottom electrode vias;
depositing bottom electrode material into the bottom electrode vias and planarizing a same to form the two bottom electrodes, thereby obtaining the substrate layer.

In some embodiments, performing the single etching process on the first hard mask layer, the magnetic tunnel junction, and the spin-orbit torque layer using the same mask comprises:
forming a magnetic layer on an upper surface of the first hard mask layer;
forming a second hard mask layer on an upper surface of the magnetic layer; and
performing a single etching process on the second hard mask layer, the magnetic layer, the first hard mask layer, the magnetic tunnel junction, and the spin-orbit torque layer using the same mask, and controlling an etching endpoint to be no higher than the lower surface of the spin-orbit torque layer.

### BRIEF DESCRIPTION OF THE DRAWINGS

FIG. 1 is a structural diagram of a magnetic storage unit according to some embodiments of the present disclosure;

FIG. 2 is a top view of FIG. 1;

FIG. 3 is a structural diagram of a magnetic storage unit according to an exemplary embodiment of the present disclosure;

FIG. 4 is a structural diagram of a magnetic storage unit according to another exemplary embodiment of the present disclosure;

FIG. 5 is a structural diagram of a magnetic storage unit according to yet another exemplary embodiment of the present disclosure;

FIG. 6 is a top view of FIG. 5;

FIG. 7 is a flowchart of a preparation method for a magnetic storage unit according to some embodiments of the present disclosure;

FIG. 8 is a substrate structure in a preparation method for a magnetic storage unit according to an exemplary embodiment of the present disclosure;

FIG. 9 is a structure of vias prepared in a substrate in a preparation method for a magnetic storage unit according to an exemplary embodiment of the present disclosure;

FIG. 10 is a structure after preparing bottom electrodes in a preparation method for a magnetic storage unit according to an exemplary embodiment of the present disclosure;

FIG. 11 is a structure after preparing a spin-orbit torque layer, a magnetic tunnel junction, a first hard mask, and a magnetization layer in a preparation method for a magnetic storage unit according to an exemplary embodiment of the present disclosure;

FIG. 12 is a structure after etching a spin-orbit torque layer, a magnetic tunnel junction, a first hard mask layer, and a magnetization layer in a preparation method for a magnetic storage unit according to an exemplary embodiment of the present disclosure;

FIG. 13 is a structure after depositing and planarizing a dielectric in a preparation method for a magnetic storage unit according to an exemplary embodiment of the present disclosure;

FIG. 14 is a structure after preparing a top electrode in a preparation method for a magnetic storage unit according to an exemplary embodiment of the present disclosure;

FIG. 15 is a substrate structure in another preparation method for a magnetic storage unit according to an exemplary embodiment of the present disclosure;

FIG. 16 is a structure of vias prepared in another substrate in a preparation method for a magnetic storage unit according to an exemplary embodiment of the present disclosure;

FIG. 17 is a structure after preparing bottom electrodes in another preparation method for a magnetic storage unit according to an exemplary embodiment of the present disclosure;

FIG. 18 is a structure after preparing a spin-orbit torque layer, a magnetic tunnel junction, a first hard mask layer, and a magnetization layer in another preparation method for a magnetic storage unit according to an exemplary embodiment of the present disclosure;

FIG. 19 is a structure after etching a spin-orbit torque layer, a magnetic tunnel junction, a first hard mask layer, and a magnetization layer in another preparation method for a magnetic storage unit according to an exemplary embodiment of the present disclosure;

FIG. 20 is a structure after depositing and planarizing a dielectric in a preparation method for another magnetic storage unit according to an exemplary embodiment of the present disclosure;

FIG. 21 is a structure after preparing a top electrode in another preparation method for a magnetic storage unit according to an exemplary embodiment of the present disclosure;

FIG. 22 is a substrate structure in yet another preparation method for a magnetic storage unit according to an exemplary embodiment of the present disclosure;

FIG. 23 is a structure of vias prepared in a substrate in yet another preparation method for a magnetic storage unit according to an exemplary embodiment of the present disclosure;

FIG. 24a is a structure after preparing bottom electrodes in yet another preparation method for a magnetic storage unit according to an exemplary embodiment of the present disclosure;

FIG. 24b is a top view of FIG. 24a;

FIG. 25 is a structure after preparing a spin-orbit torque layer, a magnetic tunnel junction, and a first hard mask layer in yet another preparation method for a magnetic storage unit according to an exemplary embodiment of the present disclosure;

FIG. 26 is a structure after etching a spin-orbit torque layer, a magnetic tunnel junction, and a first hard mask layer in yet another preparation method for a magnetic storage unit according to an exemplary embodiment of the present disclosure;

FIG. 27 is a structure after depositing and planarizing a dielectric in yet another preparation method for a magnetic storage unit according to an exemplary embodiment of the present disclosure;

FIG. 28 is a structure after preparing a top electrode in yet another preparation method for a magnetic storage unit according to an exemplary embodiment of the present disclosure;

FIG. 29 is another top view of FIG. 1;

FIG. 30 is a structural diagram of a magnetic storage unit according to yet another exemplary embodiment of the present disclosure;

FIG. 31 is a substrate structure in another preparation method for a magnetic storage unit according to an exemplary embodiment of the present disclosure;

FIG. 32 is a structure of vias prepared in another substrate in a preparation method for a magnetic storage unit according to an exemplary embodiment of the present disclosure;

FIG. 33 is a structure after preparing bottom electrodes in another preparation method for a magnetic storage unit according to an exemplary embodiment of the present disclosure;

FIG. 34 is a structure after preparing a spin-orbit torque layer, a magnetic tunnel junction, a first hard mask layer, a magnetization layer, and a second hard mask layer in a preparation method for a magnetic storage unit according to an exemplary embodiment of the present disclosure;

FIG. 35 is a structure after etching a spin-orbit torque layer, a magnetic tunnel junction, a first hard mask layer, a magnetization layer, and a second hard mask layer in a preparation method for a magnetic storage unit according to an exemplary embodiment of the present disclosure;

FIG. 36 is a structure after depositing and planarizing a dielectric in a preparation method for another magnetic storage unit according to an exemplary embodiment of the present disclosure; and

FIG. 37 is a structure after preparing a top electrode in another preparation method for a magnetic storage unit according to an exemplary embodiment of the present disclosure.

### DETAILED DESCRIPTION OF THE EMBODIMENTS

To make objectives, technical solutions, and advantages of embodiments of the present disclosure more clear, the technical solutions in the embodiments of the present disclosure are clearly and completely described in conjunction with the accompanying drawings in the embodiments of the present disclosure as below, and it is apparent that the described embodiments are only a part rather all of embodiments of the present disclosure. Based on the embodiments of the present disclosure, all other embodiments obtained by those of ordinary skill in the art without creative labor shall fall within the scope of protection of the present disclosure.

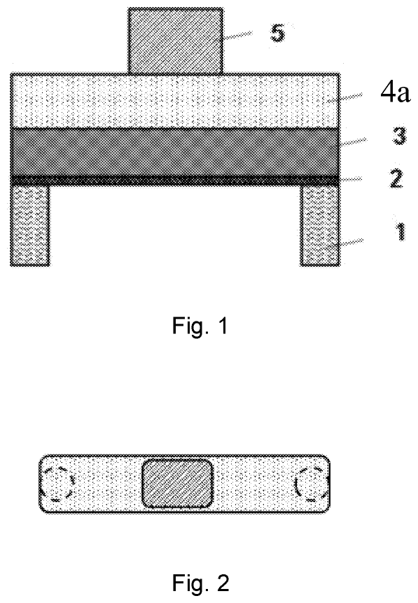

Some embodiments of the present disclosure provide a magnetic storage unit, as shown in FIG. 1 to FIG. 2, including:
a substrate layer, which includes two bottom electrodes 1 disposed at intervals,
where in some embodiments, the substrate layer typically includes two bottom electrodes 1 and a dielectric, with upper surfaces of the bottom electrodes 1 and the dielectric having the same height, and a bottom electrode material is a metallic material such as W, TiN, Ta, and TaN;
a spin-orbit torque layer 2, disposed on the upper surface of the substrate layer, and at least covering the two bottom electrodes 1,
where in some embodiments, the spin-orbit torque layer 2 usually uses heavy metals or topological materials with a large spin Hall angle, such as W, Ta, Pt, or BiSe; and
a magnetic tunnel junction 3, disposed on an upper surface of the spin-orbit torque layer 2, with an orthogonal projection of the magnetic tunnel junction 3 on the spin-orbit torque layer 2 at least covering orthogonal projections of the two bottom electrodes 1 on the spin-orbit torque layer 2,
where in some embodiments, the magnetic tunnel junction typically includes a stacked structure formed by a free layer, a barrier layer, and a reference layer, with the free layer located at the bottommost layer of the magnetic tunnel junction.

In the technical solution provided in these embodiments, both the magnetic tunnel junction 3 and the spin-orbit torque layer 2 cover the two bottom electrodes 1, which effectively provide a larger over-etching window, significantly reducing short circuits caused by re-sputtering, while reducing a probability of the spin-orbit torque layer 2 being etched through due to over-etching, thereby improving a device yield. Meanwhile, since both the magnetic tunnel junction 3 and the spin-orbit torque layer 2 cover the two bottom electrodes 1, a distance between the two bottom electrodes 1 is reduced during preparation, which helps shorten a length of the spin-orbit torque layer 2, reduce energy consumption, and lower current thermal effects, to prolong the device life. In addition, the magnetic storage unit provided by the present disclosure has strong compatibility and is directly connected to an underlying metal, reducing a series resistance in a circuit.

As some optional implementations, an edge of the magnetic tunnel junction 3 is aligned with an edge of the spin-orbit torque layer 2.

In some embodiments, aligning the edge of the magnetic tunnel junction 3 with the edge of the spin-orbit torque layer 2 enables the etching of the magnetic tunnel junction 3 and the spin-orbit torque layer 2 to be completed through a single etching method during processing, thereby effectively simplifying a preparation process.

As some optional implementations, the magnetic tunnel junction is rectangular or elliptical in shape.

As some optional implementations, an aspect ratio of the magnetic tunnel junction is less than 6.

As some optional implementations, the two bottom electrodes are circular or elliptical in shape.

As shown in FIG. 2 and FIG. 29, FIG. 2 and FIG. 29 are two top views of FIG. 1, respectively, wherein, as shown in FIG. 2, the shape of the two bottom electrodes is circular. As shown in FIG. 29, the shape of the two bottom electrodes is elliptical.

As some optional implementations, as shown in FIG. 29, when the two bottom electrodes are elliptical, a major axis direction of each bottom electrode is perpendicular to a major axis direction of the magnetic tunnel junction.

As some optional implementations, the magnetic tunnel junction includes a ferromagnetic layer, a barrier layer, and a pinned layer, and the ferromagnetic layer is located above the spin-orbit torque layer and is in direct contact with the spin-orbit torque layer.

As some optional implementations, the magnetic storage unit further includes:
a first hard mask layer 4a, which is disposed on an upper surface of the magnetic tunnel junction 3, with an edge of the first hard mask layer 4a aligned with the edge of the magnetic tunnel junction 3.

In some embodiments, a hard mask material is Ta, TaN, TiN, etc. Aligning the edge of the first hard mask layer 4a, the edge of the magnetic tunnel junction 3, and the edge of the spin-orbit torque layer 2 enables the etching of the first hard mask layer 4a, the magnetic tunnel junction 3, and the spin-orbit torque layer 2 to be completed through the single etching method during processing, thereby effectively simplifying the preparation process.

As some optional implementations, the magnetic storage unit further includes:
a magnetic layer 6, which is disposed on an upper surface of the first hard mask layer 4a, with an edge of the magnetic layer 6 aligned with the edge of the first hard mask layer 4a.

In some embodiments, a material of the magnetic layer 6 is a metallic material such as Co and Fe. Aligning the magnetic layer 6, the edge of the first hard mask layer 4a, the edge of the magnetic tunnel junction 3, and the edge of the spin-orbit torque layer 2 enables the etching of the magnetic layer 6, the first hard mask layer 4a, the magnetic tunnel junction 3, and the spin-orbit torque layer 2 to be completed through the single etching method during processing, thereby effectively simplifying the preparation process.

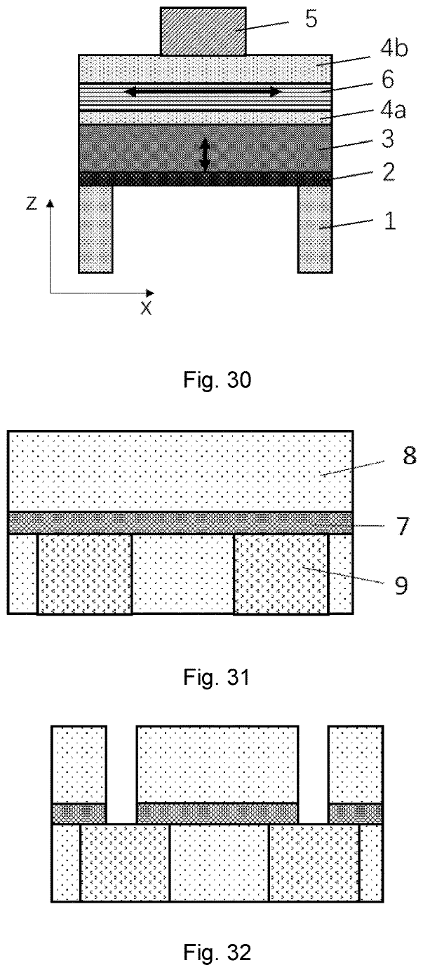

As shown in FIG. 30, the magnetic storage unit further includes:
a second hard mask layer 4b, which is disposed on a upper surface of the magnetic layer 6, with an edge of the second hard mask layer 4b aligned with an edge of the magnetic layer 6.

As some optional implementations, a magnetization direction of the magnetic layer 6 is located in a plane of the magnetic layer 6 or in a normal direction of the magnetic layer 6.

As some optional implementations, the two bottom electrodes 1 are disposed in a major axis direction of the spin-orbit torque layer 2, or a disposition direction of the two bottom electrodes 1 forms an included angle with the major axis direction of the spin-orbit torque layer.

As some optional implementations, a magnetization direction of the free layer of the magnetic tunnel junction 3 is disposed in a major axis direction of the free layer, or the magnetization direction of the free layer of the magnetic tunnel junction 3 is disposed in a normal direction of the free layer.

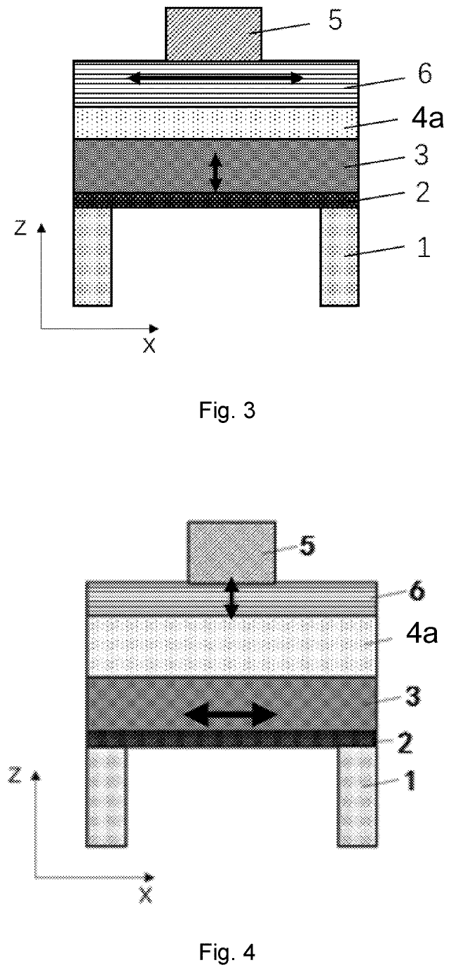

As shown in FIG. 3, some exemplary implementations are provided to exemplarily illustrate the technical solution of the present disclosure. The magnetic storage unit in FIG. 3 includes:

two bottom electrodes 1, a spin-orbit torque layer 2, a magnetic tunnel junction 3, a metal first hard mask layer 4a, an optional horizontal magnetic layer 6, and a top electrode 5 disposed sequentially from bottom to top. The spin-orbit torque layer 2, the magnetic tunnel junction 3, the metal first hard mask layer 4a, and the optional horizontal magnetic layer 6 have the same shape and are formed by a single etching step, and have an elongated shape after etching, and the bottom electrodes 1 are covered by the magnetic tunnel junction 3. A magnetization direction of the magnetic tunnel junction 3 is in a direction perpendicular to a wafer substrate direction (z), and a magnetization direction of the optional horizontal magnetic layer 6 is in an x-direction, providing a bias field for the magnetic tunnel junction 3 to enable the magnetic tunnel junction 3 to switch without an external field. In this device, a long axis of the magnetic tunnel junction 3 is in a write current direction (x). By applying current to the two bottom electrodes 1, a spin current with a magnetization direction in a y-direction is generated. Combined with a horizontal magnetic field generated by the horizontal magnetic layer 6, a write operation of the device is achieved. A read operation of the device is achieved by applying current to the bottom electrode 1 at one end and the top electrode 5. As some implementations, a material of the bottom electrode 1 is W, with a characteristic size of 40 nm; the spin-orbit torque layer 2 is W, with a thickness of 3 nm to 5 nm; materials of a free layer/dielectric/reference layer of the magnetic tunnel junction 3 are CoFeB, MgO, and CoFeB, with a free layer thickness of 1 nm to 2 nm; and a size of the magnetic tunnel junction 3 is 300 nm×60 nm.

As shown in FIG. 30, some exemplary implementations are provided to exemplarily illustrate the technical solution of the present disclosure. The magnetic storage unit in FIG. 30 includes:
two bottom electrodes 1, a spin-orbit torque layer 2, a magnetic tunnel junction 3, a metal first hard mask layer 4a, an optional vertical magnetic layer 6, a metal second hard mask layer 4b, and a top electrode 5 disposed sequentially from bottom to top. The spin-orbit torque layer 2, the magnetic tunnel junction 3, the metal first hard mask layer 4a, a metal second hard mask layer 4b, and the optional vertical magnetic layer 6 have the same shape and are formed by a single etching step, and have an elongated shape after etching, and the bottom electrodes 1 are covered by the magnetic tunnel junction 3. A magnetization direction of the magnetic tunnel junction 3 is in a direction perpendicular to a wafer substrate direction (z), and a magnetization direction of the optional vertical magnetic layer 6 is in an x-direction, providing a bias field for the magnetic tunnel junction 3 to enable the magnetic tunnel junction 3 to switch without an external field. In this device, a long axis of the magnetic tunnel junction 3 is in a write current direction (x). By applying current to the two bottom electrodes 1, a spin current with a magnetization direction in a y-direction is generated. Combined with a horizontal magnetic field generated by the vertical magnetic layer 6, a write operation of the device is achieved. A read operation of the device is achieved by applying current to the bottom electrode 1 at one end and the top electrode 5. As some implementations, a material of the bottom electrode 1 is W, with a characteristic size of 40 nm; the spin-orbit torque layer 2 is W, with a thickness of 3 nm to 5 nm; materials of a free layer/dielectric/reference layer of the magnetic tunnel junction 3 are CoFeB, MgO, and CoFeB, with a free layer thickness of 1 nm to 2 nm; and a size of the magnetic tunnel junction 3 is 300 nm×60 nm.

As shown in FIG. 4, some exemplary implementations are provided to exemplarily illustrate the technical solution of the present disclosure. The magnetic storage unit in FIG. 4 includes:
two bottom electrodes 1, a spin-orbit torque layer 2, a magnetic tunnel junction 3, a metal first hard mask layer 4a, an optional vertical magnetic layer 6, and a top electrode 5 disposed sequentially from bottom to top. The spin-orbit torque layer 2, the magnetic tunnel junction 3, the metal first hard mask layer 4a, and the optional vertical magnetic layer 6 have the same phase shape and are formed by a single etching step, and have an elongated shape after etching, and the bottom electrodes 1 are covered by the magnetic tunnel junction 3. The magnetic storage unit is a type-X spin-orbit torque magnetic memory device. A magnetization direction of the magnetic tunnel junction 3 is in a wafer substrate surface direction (x), and the optional vertical magnetic layer 6 has a magnetization direction in a z-direction, providing a bias field for the magnetic tunnel junction 3 to enable switching without an external field. In this device, a long axis of the magnetic tunnel junction 3 is in a write current direction (x). By applying current to the two bottom electrodes 1, a spin current with a magnetization in a y-direction is generated on an upper surface of an spin-orbit torque layer. Combined with a z-direction magnetic field generated by the vertical magnetic layer 6, a write operation of the device is implemented. A read operation of the device is achieved by applying current to the bottom electrode 1 at one end and the top electrode 5. As some implementations, a material of the bottom electrode 1 is W, with a characteristic size of 50 nm; the spin-orbit torque layer 2 is W, with a thickness of 3 nm to 5 nm; materials of a free layer/dielectric/reference layer of the magnetic tunnel junction 3 are CoFeB, MgO, and CoFeB, with a free layer thickness of 2 nm to 4 nm; and a size of the magnetic tunnel junction 3 is 300 nm×60 nm.

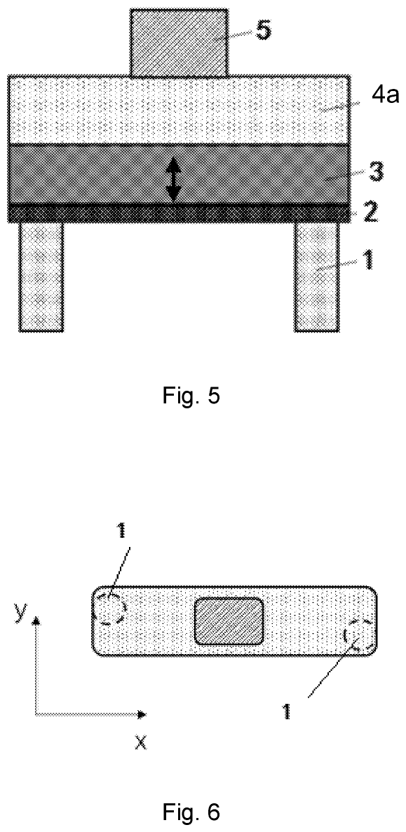

As shown in FIG. 5 and FIG. 6, some exemplary implementations are provided to exemplarily illustrate the technical solution of the present disclosure. The magnetic storage unit in FIG. 5 and FIG. 6 includes:
two bottom electrodes 1, a spin-orbit torque layer 2, a magnetic tunnel junction 3, a metal first hard mask layer 4a, and a top electrode 5 disposed sequentially from bottom to top. The spin-orbit torque layer 2, the magnetic tunnel junction 3, and the metal first hard mask layer 4a have the same shape and are formed by a single etching step, and have an elongated shape after etching, and the bottom electrodes 1 are covered by the magnetic tunnel junction 3. In this structure, a certain included angle is formed between a line connecting centers of the two bottom electrodes 1 and the x-direction. A magnetization direction of the magnetic tunnel junction 3 is in a direction perpendicular to a wafer substrate surface direction (in the z-direction). A long axis of the magnetic tunnel 3 junction is in the x-direction. After applying a write current, a generated spin current forms an included angle with the x-direction. In this case, a write operation of the device is achieved without an external magnetic field. By applying current to the bottom electrode 1 at one end and the top electrode 5, a read operation of the device is achieved. As some implementations, a material of the bottom electrode 1 is W, with a characteristic size of 50 nm; the spin-orbit torque layer 2 is W, with a thickness of 3 nm to 5 nm; materials of a free layer/dielectric/reference layer of the magnetic tunnel junction 3 are CoFeB, MgO, and CoFeB, with a free layer thickness of 1 nm to 2 nm; and a size of the magnetic tunnel junction 3 is 300 nm×100 nm.

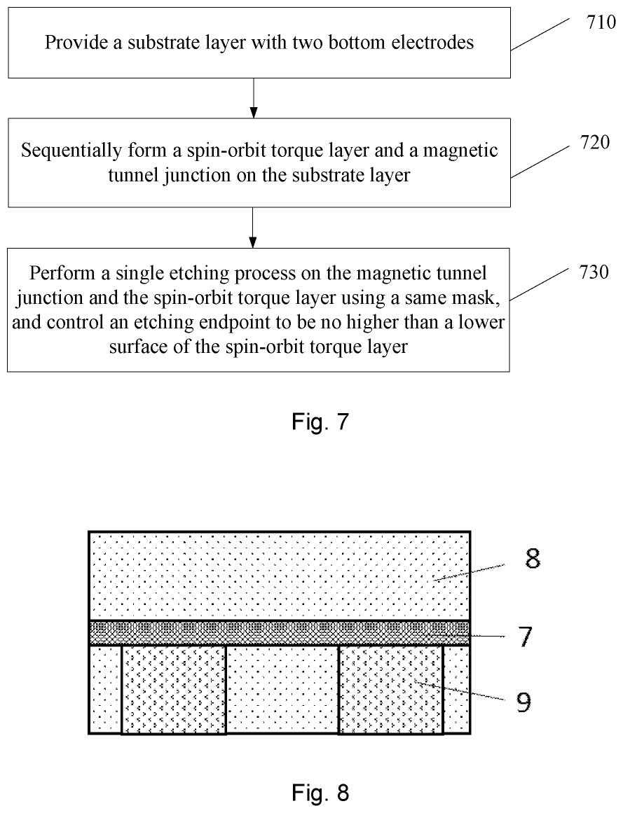

Some embodiments of the present disclosure also provide a preparation method for a magnetic storage unit. As shown in FIG. 7, the method includes:

Step 710: Provide a substrate layer with two bottom electrodes.

Step 720: Sequentially form a spin-orbit torque layer and a magnetic tunnel junction on the substrate layer.

Step 730: Perform a single etching process on the magnetic tunnel junction and the spin-orbit torque layer using a same mask, and control an etching endpoint to be no higher than a lower surface of the spin-orbit torque layer.

As some implementations, a distance between the etching endpoint and the lower surface of the spin-orbit torque layer is greater than 5 nm.

As some implementations, the step of performing a single etching process on the magnetic tunnel junction and the spin-orbit torque layer using the same mask includes:
forming a first hard mask layer on an upper surface of the magnetic tunnel junction; and
performing a single etching process on the hard mask layer, the magnetic tunnel junction, and the spin-orbit torque layer using the same mask, and controlling an etching endpoint to be no higher than the lower surface of the spin-orbit torque layer.

As some implementations, the performing a single etching process on the hard mask layer, the magnetic tunnel junction, and the spin-orbit torque layer using the same mask includes:
forming a magnetic layer on an upper surface of the hard mask layer; and
performing a single etching process on the magnetic layer, the hard mask layer, the magnetic tunnel junction, and the spin-orbit torque layer using the same mask, and controlling an etching endpoint to be no higher than the lower surface of the spin-orbit torque layer.

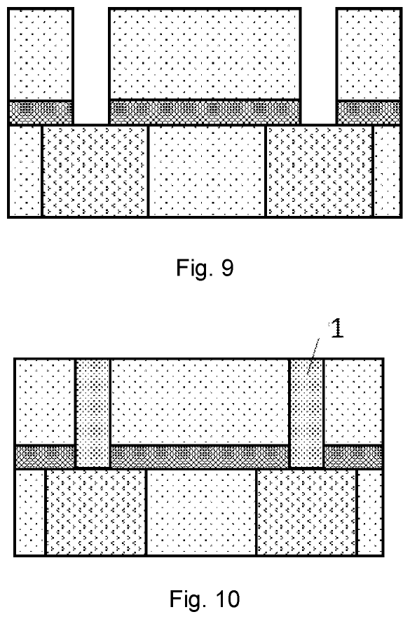

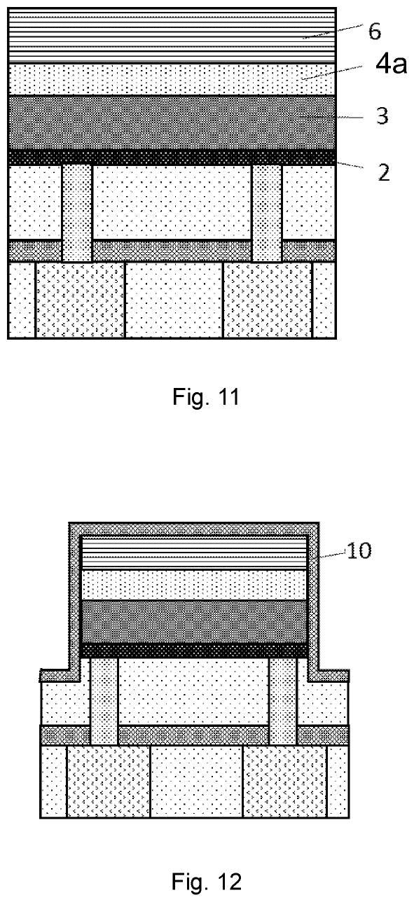

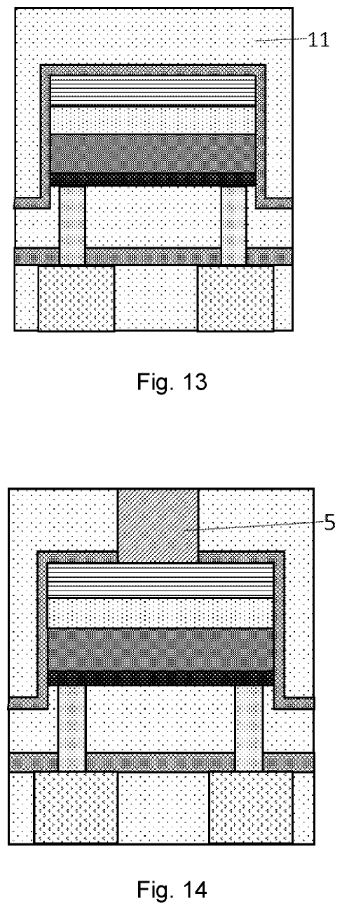

As shown in FIG. 8 to FIG. 14, some exemplary implementations are provided to exemplarily illustrate the technical solution of the present disclosure. The preparation method for a magnetic storage unit in FIG. 8 to FIG. 14 includes:
as shown in FIG. 8, depositing a first dielectric layer 7 and a second dielectric layer 8 on a substrate with bottom electrodes 9 formed, where a material of the bottom electrodes 9 is typically Cu, Ta, TaN, TiN, etc, a material of the first dielectric layer 7 is SIN, SiNC, Al₂O₃, etc., and a material of the second dielectric layer 8 is SiO₂, SiCO, etc
as shown in FIG. 9, preparing bottom electrode vias by patterning and etching;
as shown in FIG. 10, depositing and planarizing the bottom electrode material to prepare bottom electrodes 1, where the material of the bottom electrodes is a metallic material such as W, TiN, and TaN, and a planarization process is implemented by chemical mechanical lapping or etching;
as shown in FIG. 11, depositing a spin-orbit torque layer 2, a magnetic tunnel junction 3, a first hard mask layer 4a, and an optional horizontal magnetic layer 6, where the spin-orbit torque layer is made of a material with a spin Hall angle, such as W, Pt, and Ta, while the optional horizontal magnetic layer is made of a magnetic material such as Co, Fe, CoFe, CoPt, and FeNi;
as shown in FIG. 12, obtaining the magnetic tunnel junction with a required shape by patterning and etching the magnetic tunnel junction, and depositing a dielectric protective layer 10, where after etching, the magnetic tunnel junction has an elongated shape, and a material of the dielectric protective layer 10 is SiN, SiNC, or other materials;
as shown in FIG. 13, depositing and planarizing the third dielectric layer 11, where a material of the third dielectric layer 11 is SiO₂, SiCO, etc; and
as shown in FIG. 14, preparing a top electrode 5 through patterning, etching, filling with a top electrode material, and planarization. Typically, a material of the top electrode is a metallic material such as Cu, W, and TaN.

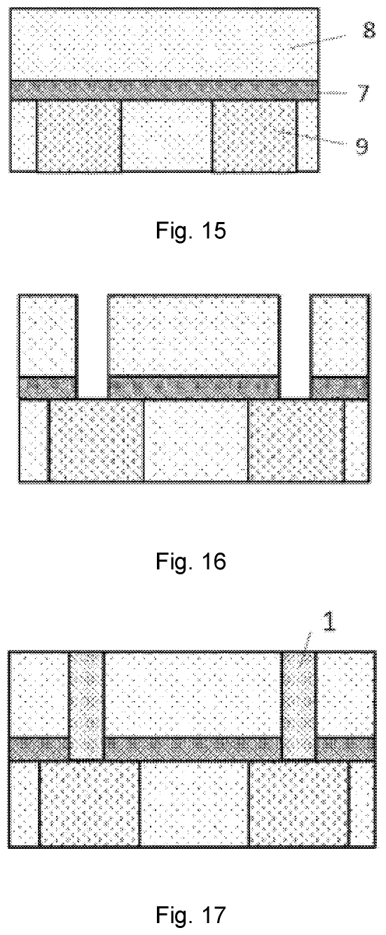

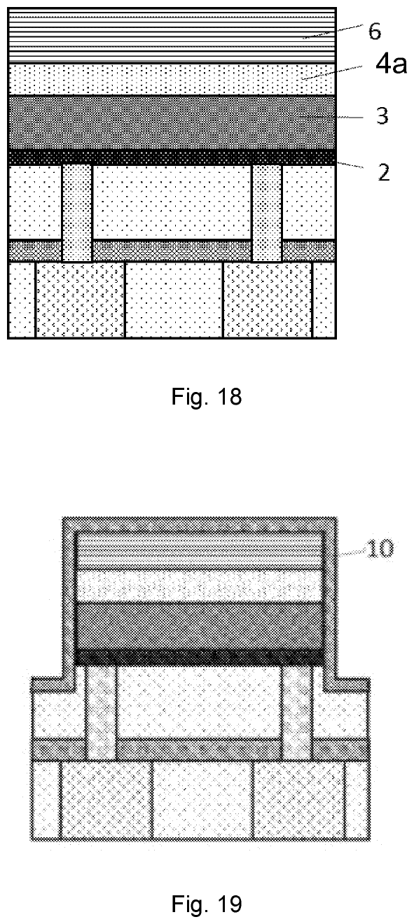

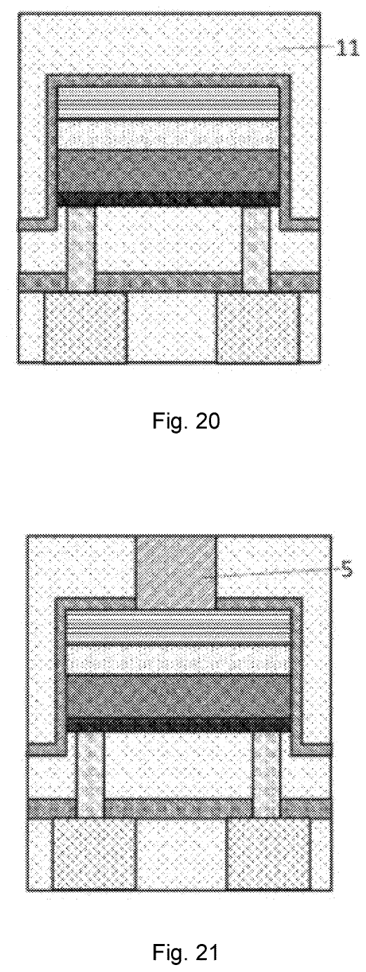

As shown in FIG. 15 to FIG. 21, some exemplary implementations are provided to exemplarily illustrate the technical solution of the present disclosure. The preparation method for a magnetic storage unit in FIG. 15 to FIG. 21 includes:
as shown in FIG. 15, depositing a first dielectric layer 7 and a second dielectric layer 8 on a substrate with bottom electrodes 9 formed, where a material of the bottom electrodes 9 is typically Cu, Ta, TaN, TiN, etc, a material of the first dielectric layer 7 is SIN, SiNC, Al₂O₃, etc., and a material of the second dielectric layer 8 is SiO₂, SiCO, etc;
as shown in FIG. 16, preparing bottom electrode vias by patterning and etching;
as shown in FIG. 17, depositing and planarizing the bottom electrode material to prepare bottom electrodes 1, where a material of the bottom electrodes is a metallic material such as W, TiN, and TaN, and a planarization process is implemented by chemical mechanical lapping or etching;
as shown in FIG. 18, depositing a spin-orbit torque layer 2, a magnetic tunnel junction 3, a first hard mask layer 4a, and an optional horizontal magnetic layer 6, where the spin-orbit torque layer is made of a material with a spin Hall angle, such as W, Pt, Ta, and BiSe, while the optional horizontal magnetic layer is made of a magnetic material, such as an FePt or CoPt multilayer film, another magnetic multilayer film, or an alloy;
as shown in FIG. 19, obtaining the magnetic tunnel junction with a required shape by patterning and etching the magnetic tunnel junction, and depositing a dielectric protective layer, where after etching, the magnetic tunnel junction has an elliptical shape, and a material of the dielectric protective layer 10 is SIN, SiNC, or other materials;
as shown in FIG. 20, depositing and planarizing the third dielectric layer 11, where a material of the third dielectric layer 11 is SiO₂, SiCO, etc; and
as shown in FIG. 21, preparing a top electrode 5 through patterning, etching, filling with a top electrode material, and planarization. Typically, a material of the top electrode is a metallic material such as Cu, W, and TaN.

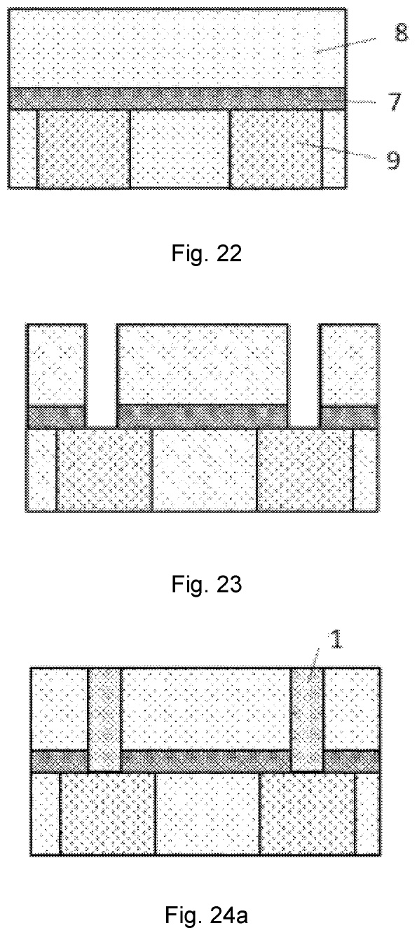

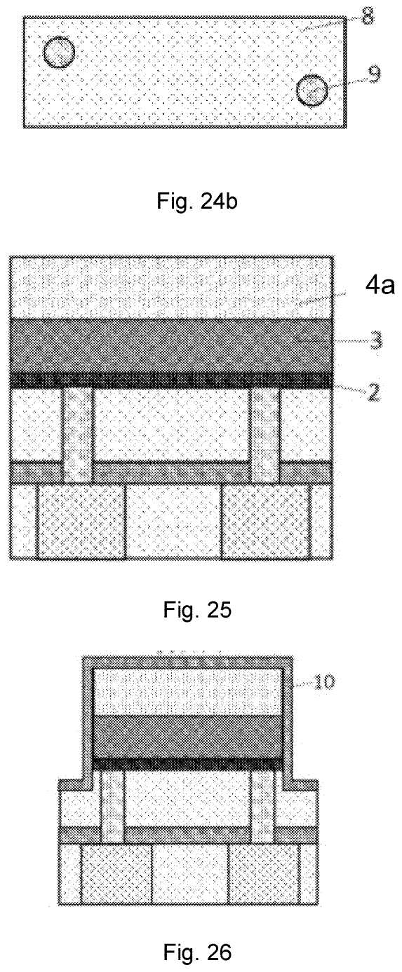

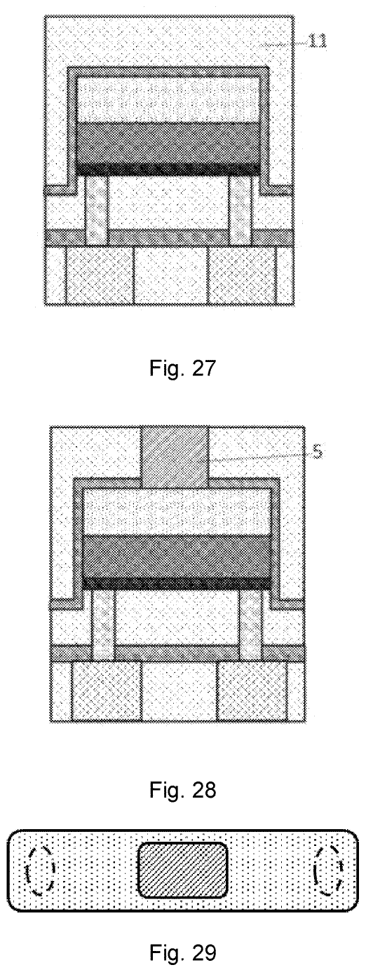

As shown in FIG. 22 to FIG. 28, some exemplary implementations are provided to exemplarily illustrate the technical solution of the present disclosure. The preparation method for a magnetic storage unit in FIG. 22 to FIG. 28 includes:
as shown in FIG. 22, depositing a first dielectric layer 7 and a second dielectric layer 8 on a substrate with bottom electrodes 9 formed, where a material of the bottom electrodes 9 is typically Cu, Ta, TaN, TiN, etc, a material of the first dielectric layer 7 is SIN, SiNC, Al₂O₃, etc., and a material of the second dielectric layer 8 is SiO₂, SiCO, etc;
as shown in FIG. 23, preparing bottom electrode vias by patterning and etching;
as shown in FIG. 24a, depositing and planarizing the bottom electrode material to prepare bottom electrodes 1, where the material of the bottom electrodes is a metallic material such as W, TiN, and TaN, a planarization process is implemented by chemical mechanical lapping or etching, and as shown in FIG. 24b, a certain included angle is formed between a line connecting centers of the two bottom electrodes and the x-direction in this structure;
as shown in FIG. 25, depositing a spin-orbit torque layer 2, a magnetic tunnel junction 3, and a first hard mask layer 4a, where the spin-orbit torque layer is made of a material with a spin Hall angle, such as W, Pt, and Ta;
as shown in FIG. 26, obtaining the magnetic tunnel junction with a required shape by patterning and etching the magnetic tunnel junction, and depositing a dielectric protective layer, where after etching, the magnetic tunnel junction has an elongated shape, and a material of the dielectric protective layer 10 is SIN, SiNC, or other materials;
as shown in FIG. 27, depositing and planarizing a third dielectric layer 11, where a material of the third dielectric layer 11 is SiO₂, SiCO, etc; and
as shown in FIG. 28, preparing a top electrode 5 through patterning, etching, filling with a top electrode material, and planarization. Typically, a material of the top electrode is a metallic material such as Cu, W, and TaN.

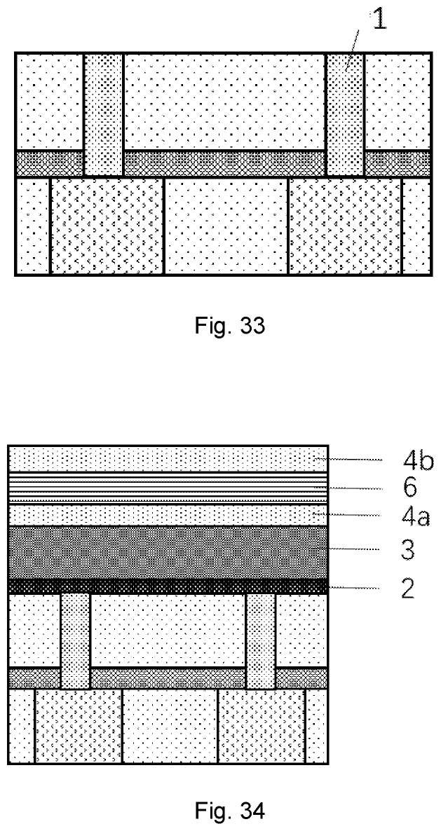

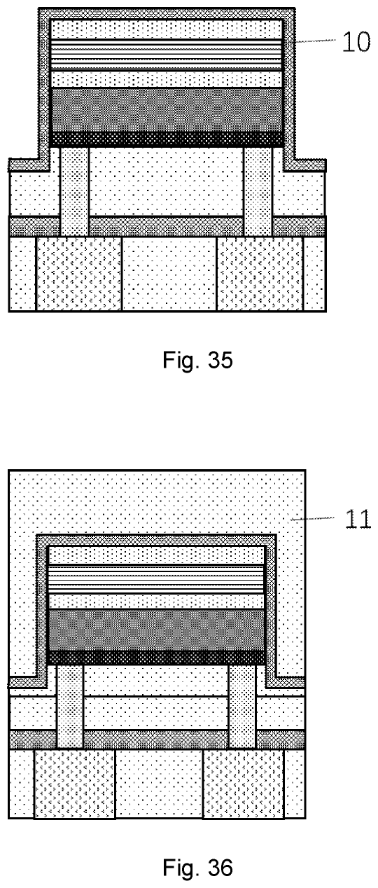

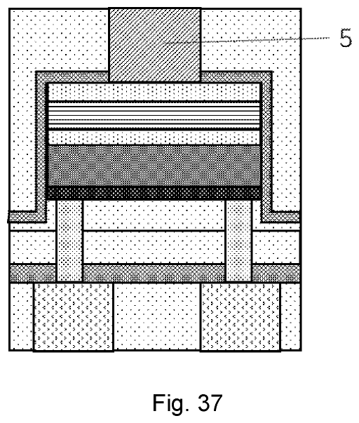

As shown in FIG. 31 to FIG. 37, some exemplary implementations are provided to exemplarily illustrate the technical solution of the present disclosure. The preparation method for a magnetic storage unit in FIG. 31 to FIG. 37 includes:
as shown in FIG. 31, depositing a first dielectric layer 7 and a second dielectric layer 8 on a substrate with bottom electrodes 9 formed, where a material of the bottom electrodes 9 is typically Cu, Ta, TaN, TIN, etc, a material of the first dielectric layer 7 is SiN, SiNC, Al₂O₃, etc., and a material of the second dielectric layer 8 is SiO₂, SiCO, etc;
as shown in FIG. 32, preparing bottom electrode vias by patterning and etching;
as shown in FIG. 33, depositing and planarizing the bottom electrode material to prepare bottom electrodes 1, where the material of the bottom electrodes is a metallic material such as W, TiN, and TaN, and a planarization process is implemented by chemical mechanical lapping or etching;
as shown in FIG. 34, depositing a spin-orbit torque layer 2, a magnetic tunnel junction 3, a first hard mask layer 4a, an optional horizontal magnetic layer 6, and a second hard mask layer 4b, where the spin-orbit torque layer is made of a material with a spin Hall angle, such as W, Pt, Ta, and BiSe while the optional horizontal magnetic layer is made of a magnetic material such as FePt, CoPt; the thickness of the first hard mask layer 4a is adjustable, allowing for the adjustment of the horizontal magnetic field strength at the free layer by tuning the thickness of the first hard mask layer 4a;
as shown in FIG. 35, obtaining the magnetic tunnel junction with a required shape by patterning and etching the magnetic tunnel junction, and depositing a dielectric protective layer 10, where after etching, the magnetic tunnel junction has an elliptical shape, and a material of the dielectric protective layer 10 is SiN, SiNC, or other materials;
as shown in FIG. 36, depositing and planarizing the third dielectric layer 11, where a material of the third dielectric layer 11 is SiO₂, SiCO, etc; and
as shown in FIG. 37, preparing a top electrode 5 through patterning, etching, filling with a top electrode material, and planarization. Typically, a material of the top electrode is a metallic material such as Cu, W, and TaN.

The above descriptions are merely specific implementations of the present disclosure, but the scope of protection of the present disclosure is not limited to this; and any variations or substitutions that are easily conceived by those skilled in the art within the technical scope disclosed by the present disclosure shall fall within the scope of protection of the present disclosure. Therefore, the scope of protection of the present disclosure shall be subject to the appended claims.

1. A magnetic storage unit, comprising:
a substrate layer, which comprises two bottom electrodes disposed at intervals;
a spin-orbit torque layer, disposed on an upper surface of the substrate layer, and at least covering the two bottom electrodes; and
a magnetic tunnel junction, disposed on an upper surface of the spin-orbit torque layer, with an orthogonal projection of the magnetic tunnel junction on the spin-orbit torque layer at least covering orthogonal projections of the two bottom electrodes on the spin-orbit torque layer.

2. The magnetic storage unit as claimed in claim 1, wherein an edge of the magnetic tunnel junction is aligned with an edge of the spin-orbit torque layer.

3. The magnetic storage unit as claimed in claim 1, wherein the magnetic tunnel junction comprises a ferromagnetic layer, a barrier layer, and a pinned layer, and the ferromagnetic layer is located above the spin-orbit torque layer and is in direct contact with the spin-orbit torque layer.

4. The magnetic storage unit as claimed in claim 1, further comprising:
a first hard mask layer, which is disposed on an upper surface of the magnetic tunnel junction, with an edge of the first hard mask layer aligned with an edge of the magnetic tunnel junction.

5. The magnetic storage unit as claimed in claim 4, further comprising:
a magnetic layer, which is disposed on an upper surface of the hard mask layer, with an edge of the magnetic layer aligned with the edge of the hard mask layer.

6. The magnetic storage unit as claimed in claim 5, wherein a magnetization direction of the magnetic layer is located in a plane of the magnetic layer or in a normal direction of the magnetic layer.

7. The magnetic storage unit as claimed in claim 1, wherein the two bottom electrodes are disposed in a major axis direction of the spin-orbit torque layer, or a disposition direction of the two bottom electrodes forms an included angle with the major axis direction of the spin-orbit torque layer.

8. The magnetic storage unit as claimed in claim 1, wherein a magnetization direction of a free layer of the magnetic tunnel junction is disposed in a major axis direction of the free layer, or the magnetization direction of the free layer of the magnetic tunnel junction is disposed in a normal direction of the free layer.

9. A preparation method for a magnetic storage unit, comprising:
providing a substrate layer with two bottom electrodes;
sequentially forming a spin-orbit torque layer and a magnetic tunnel junction on the substrate layer; and
performing a single etching process on the magnetic tunnel junction and the spin-orbit torque layer using a same mask, and controlling an etching endpoint to be no higher than a lower surface of the spin-orbit torque layer.

10. The method as claimed in claim 9, wherein performing the single etching process on the magnetic tunnel junction and the spin-orbit torque layer using the same mask comprises:
forming a first hard mask layer on an upper surface of the magnetic tunnel junction; and
performing a single etching process on the first hard mask layer, the magnetic tunnel junction, and the spin-orbit torque layer using the same mask, and controlling an etching endpoint to be no higher than the lower surface of the spin-orbit torque layer.

11. The method as claimed in claim 10, wherein performing the single etching process on the first hard mask layer, the magnetic tunnel junction, and the spin-orbit torque layer using the same mask comprises:
forming a magnetic layer on an upper surface of the first hard mask layer; and
performing a single etching process on the magnetic layer, the first hard mask layer, the magnetic tunnel junction, and the spin-orbit torque layer using the same mask, and controlling an etching endpoint to be no higher than the lower surface of the spin-orbit torque layer.

12. The magnetic storage unit as claimed in claim 1, wherein the magnetic tunnel junction is rectangular or elliptical in shape.

13. The magnetic storage unit as claimed in claim 1, wherein an aspect ratio of the magnetic tunnel junction is less than 6.

14. The magnetic storage unit as claimed in claim 1, wherein the two bottom electrodes are circular or elliptical in shape.

15. The magnetic storage unit as claimed in claim 14, wherein when the two bottom electrodes are elliptical, a major axis direction of each bottom electrode is perpendicular to a major axis direction of the magnetic tunnel junction.

16. The magnetic storage unit as claimed in claim 5, further comprising:
a second hard mask layer, which is disposed on an upper surface of the magnetic layer, with an edge of the second hard mask layer aligned with an edge of the magnetic layer.

17. The method as claimed in claim 9, wherein a distance between the etching endpoint and the lower surface of the spin-orbit torque layer is greater than 5 nm.

18. The method as claimed in claim 9, wherein providing a substrate layer with two bottom electrodes comprises:
depositing a dielectric layer on a substrate having the two bottom electrodes formed thereon;
patterning and etching the dielectric layer to form bottom electrode vias;
depositing bottom electrode material into the bottom electrode vias and planarizing a same to form the two bottom electrodes, thereby obtaining the substrate layer.

19. The method as claimed in claim 11, wherein performing the single etching process on the first hard mask layer, the magnetic tunnel junction, and the spin-orbit torque layer using the same mask comprises:
forming a magnetic layer on an upper surface of the first hard mask layer;
forming a second hard mask layer on an upper surface of the magnetic layer; and
performing a single etching process on the second hard mask layer, the magnetic layer, the first hard mask layer, the magnetic tunnel junction, and the spin-orbit torque layer using the same mask, and controlling an etching endpoint to be no higher than the lower surface of the spin-orbit torque layer.
